(19) United States
(12) Patent Application Publication
(10) Pub. No.: US 2009/0045798 A1
(43) Pub. Date: Feb. 19, 2009

(54) Synchronization of Spectrum Analyzer Frequency Sweep and External Switch

(75) Inventors: Kooi Seow Heah, Simpang Ampat (MY); Wei Bee LIM, Georgetown (MY); Yew Tatt SIM, Butterworth (MY)

Correspondence Address: AGILENT TECHNOLOGIES INC., INTELLECTUAL PROPERTY ADMINISTRATION,LEGAL DEPT., MS BLDG. E P.O. BOX 7599, LOVELAND, CO, 80537, US

(73) Assignee: AGILENT TECHNOLOGIES, INC., Loveland, CO (US)

(21) Appl. No.: 11/838,294

(22) Filed: Aug. 14, 2007

(51) Int. Cl. G01R 23/00

(52) U.S. Cl. 324/76.19

(57) ABSTRACT

A measuring receiver comprises a spectrum analyzer having a local oscillator for sweeping the measurement frequency of the spectrum analyzer through multiple frequency bands. A preselector has multiple filter paths with frequency bands corresponding to frequency bands of the spectrum analyzer. The filter paths for passing signals through the preselector and outputting filtered signals to the spectrum analyzer. Switches of the preselector switch between filter paths to switch in a filter path having a frequency band corresponding to a frequency band being swept by the spectrum analyzer. A controller delays the sweeping of the measurement frequency during intervals when the switches are switching between filter paths.

### BACKGROUND OF THE INVENTION

Any product that uses the public power grid or has electronic circuitry must pass EMC (electromagnetic compatibility) requirements. EMC is essentially the opposite of EMI (electromagnetic interference). EMC means that the device is compatible with (i.e., no interference caused by) its EM environment, and it does not emit levels of electromagnetic energy that cause EMI in other devices in the vicinity. Compliance with these emission requirements requires radiated emissions testing and conducted emissions testing. EMI receivers are used to measure the characteristics of these products to make sure that they meet the emissions requirements.

Herein “measurement receiver” or “measuring receiver” is defined as a system used to examine the spectral composition of some electrical, acoustic, or optical waveform. EMI receivers are thus a subset of “measuring receivers”.

Radiated emissions testing looks for signals being emitted from the equipment under test (EUT) through space. The typical frequency range for these measurements is 30 MHz to 1 GHz, although FCC regulations require testing up to 200 GHz for an intentional radiator (such as a wireless transmitter) operating at a center frequency above 30 GHz.

Conducted emissions testing focuses on signals present on the AC mains that are generated by the EUT and these signals are usually below 30 MHz.

The CISPR frequency bands include the conducted band (“C Band”) and the radiated band (“R Band”). The radiated emissions testing is performed in the “R Band” and conducted emissions testing is performed in the “C Band”. Within the “C Band” is the “Band A” covering 9 kHz to 150 kHz and the “Band B” covering 150 kHz to 30 MHz. Within the “R Band” is the “Band C” covering 30 MHz to 300 MHz and the “Band D” covering 300 MHz to 1 GHz.

Industry standards for EMC conformance testing include CISPR, EN, FCC, VCCI, and VDE.

In order to make compliance EMC measurements, the EMI receiver must meet the requirements of CISPR publication 16 (CISPR 16) entitled “CISPR specification for radio interference measuring”. An example of a prior art EMI receiver having the characteristics recommended in CISPR 16. The Agilent E743XA EMC Receiver of the prior-art is one such receiver. The system synchronized the switching of the filters with the frequency sweep of the spectrum analyzer. The synchronization is performed by ADC pulses driving from a TPU (“time processing unit) of an RF preselector controller, through a RS232 bus transceiver, to the QPD (“Quasi-Peak Detector”) board of the spectrum analyzer.

However, more modern spectrum analyzers no longer use this RS232 bus receiver and therefore it would be desirable to find another method for synchronizing the frequency sweep of a spectrum analyzer with the switching of filter paths of a preselector.

### SUMMARY OF THE INVENTION

The present invention provides a measuring receiver including a spectrum analyzer having a local oscillator for sweeping the measurement frequency of the spectrum analyzer through multiple frequency bands. A preselector has multiple filter paths with frequency bands corresponding to frequency bands of the spectrum analyzer. The filter paths for passing signals through the preselector and outputting filtered signals to the spectrum analyzer. Switches of the preselector switch between filter paths to switch in a filter path having a frequency band corresponding to a frequency band being swept by the spectrum analyzer. A controller delays the sweeping of the measurement frequency during intervals when the switches are switching between filter paths.

### BRIEF DESCRIPTION OF THE DRAWINGS

Further preferred features of the invention will now be described for the sake of example only with reference to the following figure, in which:

FIG. 1 is a schematic block diagram showing components making up a CISPR compliant EMI receiver of an embodiment of the present invention.

FIG. 2 shows a schematic block diagram of the preselector of FIG. 1.

FIG. 3 shows the schematic block diagram of FIG. 2 with a radiated emissions RF filter path highlighted.

FIG. 4 shows the schematic block diagram of FIG. 2 with a conducted emissions RF filter path highlighted.

FIG. 5 is a more detailed schematic block diagram of the spectrum analyzer illustrated in FIG. 1.

FIG. 6 is a system level block diagram showing the control components for controlling the preselector of FIGS. 1-4.

FIG. 7 shows a method of the present invention.

FIG. 8 shows the filter overlap region in a diagram of filter pass-bands.

### DETAILED DESCRIPTION

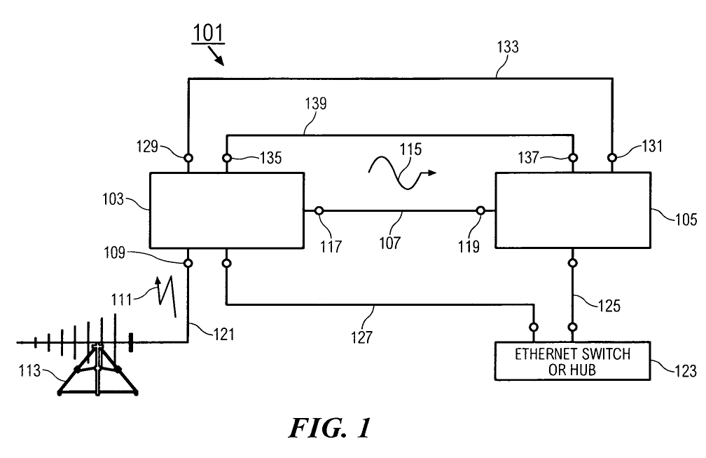

FIG. 1 is a schematic block diagram showing components making up a CISPR 16 compliant EMI receiver 101 of the present invention. The components include a preselector 103 and a spectrum analyzer 105. In general the spectrum analyzer 105 can be selected from different types of signal analyzers and the EMI receiver 101 can be selected from different types of measurement receivers.

The preselector 103 pre-filters broadband signals so that the combination of the preselector 103 and spectrum analyzer 105 becomes an EMI receiver 101 for measuring impulsive EMI signals with high dynamic range and accuracy, as specified by CISPR 16. In the operation of the EMI receiver 101, a radiated or conducted emissions signal 111 to be measured is transmitted from a source 113 through an RF cable 121 and to a preselector RF input port 109 of the preselector 103. The source 113 can be an antenna receiving radiated emission signals, for example, or can be a cable transmitting conducted emission signals. The preselector 103 prevents the compression of the input mixer of the spectrum analyzer 105 which can be caused by broadband, impulsive emissions signals 111. The preselector 103 can be an N9039A RF preselector from Agilent Technologies, Inc. of Santa Clara, Calif., USA.

A signal 115 is output from a preselector RF output port 117 of the preselector 103 through an RF cable 107 to a spectrum analyzer RF input port 119 of the spectrum analyzer 105. The spectrum analyzer can be selected from one of the PSA Series Spectrum Analyzers from Agilent Technologies, Inc. For example, the spectrum analyzer can be an E4448A PSA Series Spectrum Analyzer from Agilent Technologies, Inc. The PSA type spectrum analyzer provides the EMI receiver with broad dynamic range, accuracy and speed.

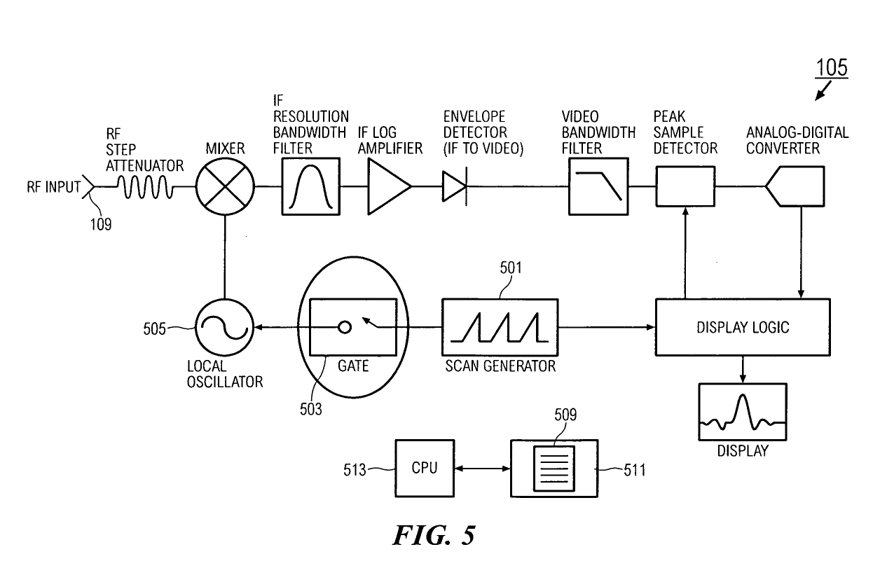

The spectrum analyzer 105 is loaded with EMC DLP software 509 stored within memory storage 511 of the spectrum analyzer 105 (see FIG. 5). The DLP, or “Downloadable Personality”, customizes the character of the spectrum analyzer 105 to enable software features in addition to the basic functions of the spectrum analyzer 105. In the present invention, the DLP software 509 adds capabilities to the spectrum analyzer 105 to control and make EMC measurements using the preselector 103. The software 509 is processed by a controller which can be a CPU 513 of the spectrum analyzer 105 executing instructions of the EMC DLP software 509.

Measurement parameters of the spectrum analyzer 105 can be changed either using a front panel UI of the spectrum analyzer 105 or else remotely through an Ethernet switch or hub 123 passing SCPI commands to the spectrum analyzer 105 through a LAN cable 125. The spectrum analyzer 105 can also update the preselector 103 of any changes to measurement parameters by passing SCPI commands through a LAN cable 127.

At the rear of the preselector 103 is a “sweep out” port 129 which is connected to an “external trigger in” port 131 at the front of the spectrum analyzer 105 via a BNC cable 133. At the rear of the preselector 103 is also a “trigger out” port 135 which is connected to a “trigger in” port 137 at the rear of the spectrum analyzer 105 via a BNC cable 139.

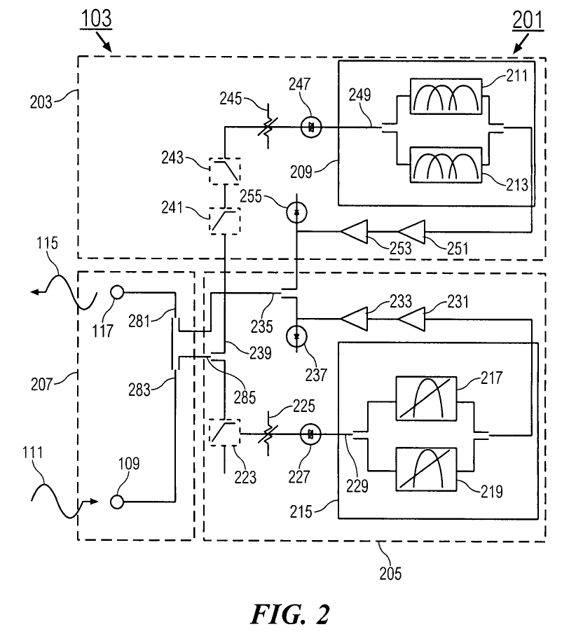

FIG. 2 shows a schematic block diagram 201 of the preselector 103 of FIG. 1. The preselector 103 includes a conducted input section 203, a radiated input section 205 and a relay switch section 207.

The preselector 103 has multiple filter paths, for example paths along the radiated and conducted emissions RF filter paths 301, 401 with frequency bands corresponding to frequency bands of the spectrum analyzer 105. The filter paths pass the input signals 111 through the preselector 103 and output filtered signals 115 to the spectrum analyzer 105. The preselector 103 has switches, for example the switches 281, 283, 285, 235, 229, 249 of FIG. 2, for switching between filter paths to switch in a filter path having a frequency band corresponding to a frequency band being swept by the spectrum analyzer.

The conducted input section 203 processes conducted emissions signals 111 in the “C Band” (9 kHz to 30 MHz). The conducted input section 203 can comprise components mounted on and connections made on a PCB (PC board). A conducted filter section 209 includes a path through a “Band A” (9 kHz to 150 kHz) filter bank 211 and a path through a “Band B” (150 kHz to 30 MHz) filter bank 213. Each of these filter banks can provide several filter paths and can include many individual filters. For example, the “Band B” filter bank 213 can have a filter for 150 kHz to 1 MHz, another filter for 1 MHz to 2 MHz, yet another filter for 2 MHz to 5 MHz and so on until 30 MHz. All these filters combined cover the 150 kHz to 30 MHz frequency range for “Band B” filter bank 213. These filters can be either analog or digital filters.

The radiated input section 205 processes radiated emissions signals 111 in the “R Band” (30 MHz to 1 GHz). The radiated input section 205 can comprise components mounted on and connections made on a PCB (PC board). A radiated filter section 215 includes a path through a “Band C” (30 MHz to 300 MHz) filter bank 217 and a path through a “Band D” (300 MHz to 1 GHz) filter bank 219. Again, each of these filter banks can provide several filter paths and can include many individual filters and these filters can be either analog or digital filters.

The relay switch section 207 is shown in FIG. 2. The relay switch section 207 provides switching between several different paths through the preselector 103. The relay switch section 207 can include the switches 281, 283 and can be implemented using an 8763C (4 RF Port) microswitch.

The EMI receiver 101 has three modes of operation: a radiated emissions mode, a conducted emissions mode, and a bypass mode.

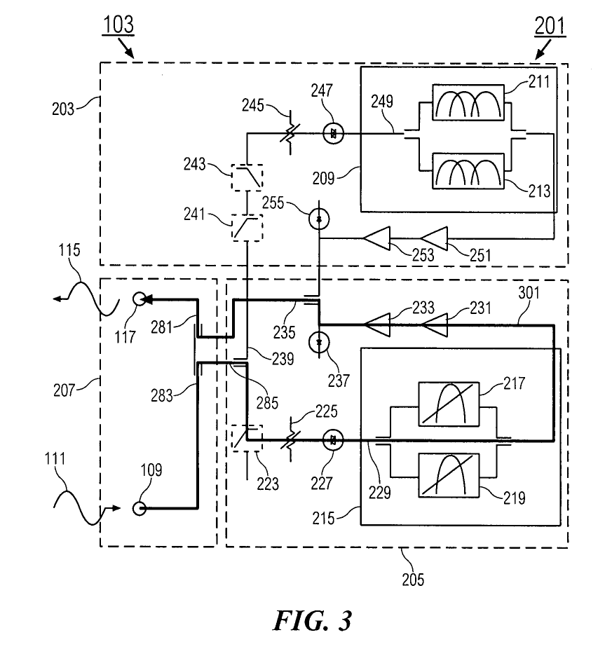

When measuring a radiated emissions signal 111 the radiated emissions mode is used. The switches 281, 283 are positioned such that the radiated emissions RF filter path 301 of FIG. 3 is switched in, providing a path from the preselector RF input port 109 into the radiated input section 205. For the case of the radiated emissions signal 111, the switch 285 is positioned such that the radiated emissions signal 111 passes through the radiated input section 205 along the “R Band” radiated emissions RF filter path 301.

The “R Band” signal 111 is above 30 MHz (30 MHz to 1 GHz) so a 30 MHz high pass filter 223 is used to filter out any low frequency noise. Next, a rugged RF input or step attenuator 225 and a limiter 227 provide input protection against large pulsed signals or other gross overloads that could damage the input attenuator or the first mixer of the spectrum analyzer 105.

The “R Band” signal 111 then enters the radiated filter section 215. The switch 229 is positioned to send the signal 111 through the tunable filter bank 217 when the signal 111 is within the “Band C” (30 MHz to 300 MHz) and the switch 229 is positioned to send the signal 111 through the tunable filter bank 219 when the signal 111 is within the “Band D” (300 MHz to 1 GHz). The preselection filters of the filter banks 217, 219 reduce the energy content of the broadband signal that the mixer of the spectrum analyzer 105 sees. This improves the dynamic range compared to using the spectrum analyzer 105 alone and allows the measurement of small signals in the presence of large ambient signals that would otherwise overload the front end of the spectrum analyzer 105. These large ambient signals are particularly a problem when trying to measure low level radiated emissions at an outdoor site where there are often many high power radio transmitters in the area.

The “R Band” signal 111 then passes through a variable gain amplifier 231 and a step gain amplifier 233. These low noise pre-amplifiers improve the system noise performance and give better sensitivity to the combined preselector 103 and spectrum analyzer 105 than the spectrum analyzer 105 used alone.

After passing from the amplifiers 231, 233, but before passing through the switch 235 and out of the radiated input section 205, the signal 111 passes through an overload detector 237. If the signal level is too large, the overload detector 237 will send a trigger to an overload status register of the preselector digital control components 601. The EMC DLP software 509 queries the overload status register and upon determining there has been an overload occurrence it will display an error message on the display of the spectrum analyzer 105. This display alerts an end user that an overload condition has occurred.

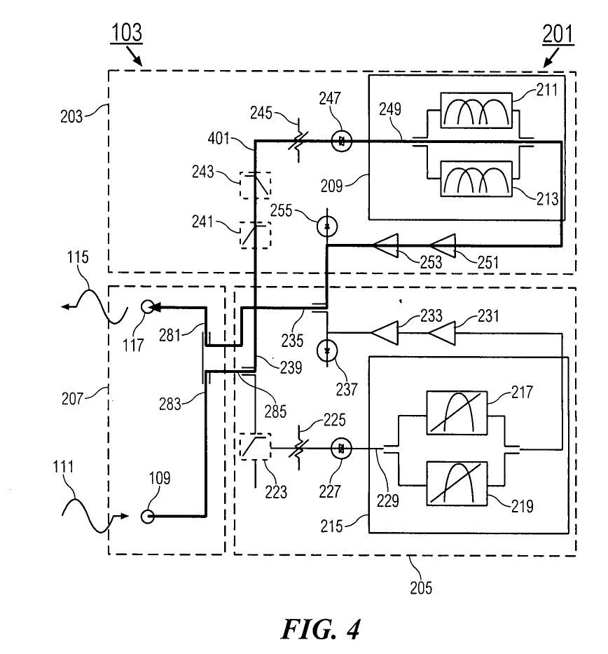

When measuring a conducted emissions signal 111 the conducted emissions mode is used. The switches 281, 283, are positioned such that the conducted emissions RF filter path 401 of FIG. 4 is switched in, providing a path from the preselector RF input port 109 into the radiated input section 205. For the case of a conducted emissions signal 111, the switch 285 is positioned such that the conducted emissions signal 111 passes along an unfiltered “C Band” path 239 of the radiated input section 205, out from the radiated input section 205, into the conducted input section 203, and back into the radiated input section 205.

The “C Band” signal 111 is between 9 kHz and 30 MHz, and so a 9 kHz high pass filter 241 and a 30 MHz low pass filter 243 are used to filter out any out-of-band noise. Next, a rugged RF input or step attenuator 245 and a limiter 247 provide input protection against large pulsed signals or other gross overloads that could damage the input attenuator or the first mixer of the spectrum analyzer 105. This protection is especially important when making conducted emissions measurements using a current clamp or LISN (Line Impedance Stabilization Network), which can generate voltage spikes of several hundred volts.

The “C Band” signal 111 then enters the conducted filter section 209. A switch 249 is positioned to send the signal 111 through the fixed filter bank 211 or the fixed filter bank 213, depending on the frequency range of the signal 111. For example, when the signal 111 is within the “Band A” (9 kHz to 150 kHz) and the switch 249 is positioned to send the signal 111 through the fixed filter bank 211. When the signal 111 is within the “Band B” (150 kHz to 30 MHz), the switch 249 is positioned to send the signal 111 through the fixed filter bank 213.

The preselection filters of the filter banks 211, 213 reduce the energy content of the broadband signal that the mixer of the spectrum analyzer 105 sees. This improves the dynamic range compared to using the spectrum analyzer 105 alone and allows for the measurement of small signals in the presence of large ambient signals that would otherwise overload the front end of the spectrum analyzer 105.

The “C Band” signal 111 then passes through a variable gain amplifier 251 and a step gain amplifier 253. These low noise pre-amplifiers improve the system noise performance and give the preselector 103 and spectrum analyzer 105 combination better sensitivity than the spectrum analyzer 105 used alone.

Before leaving the conducted input section 203, the signal 111 passes through an overload detector 255. If the signal level is too large, the overload detector 255 will send a trigger to an overload status register of the preselector digital control components 601. The EMC DLP software 509 queries the overload status register and upon determining there has been an overload occurrence it will display an error message on the display of the spectrum analyzer 105. This display alerts an end user that an overload condition has occurred.

FIG. 5 is a more detailed schematic block diagram of the spectrum analyzer 105 of FIG. 1. The input from the preselector 103 enters the spectrum analyzer 105 thorough the input port 109.

The spectrum analyzer 105 has a local oscillator (“LO”) 505 for sweeping the measurement frequency of the spectrum analyzer 105 through multiple frequency bands. A scan generator 501 generates voltage ramps, with the output of the scan generator 501 controlled by a gate 503. The combination of the scan generator 501, gate 503 and LO 505 is typically used for a time gating technique referred to as gated sweep or sometimes referred to as gated LO.

Time-gated spectrum analysis allows one to obtain spectral information about signals occupying the same part of the frequency spectrum that are separated in the time domain. Using an external trigger signal to coordinate the separation of these signals, one can perform the following operations, for example:

Measure any one of several signals separated in time; for example, one can separate the spectra of two radios time-sharing a single frequency;

Measure the spectrum of a signal in one time slot of a TDMA system; or

Exclude the spectrum of interfering signals, such as periodic pulse edge transients that exist for only a limited time.

In gated sweep mode, the voltage ramp produced by the scan generator 501 is controlled to sweep the frequencies of the LO 505 as shown in FIG. 5. When the gate 503 is open (meaning the contact is in a closed position allowing a signal to pass from the scan generator 501 to the LO 505), the LO 505 ramps up in frequency like any spectrum analyzer. When the gate 503 is closed (opening the contact and blocking the signal from passing from the scan generator 501 to the LO 505), the voltage out of the scan generator 501 is frozen, and the LO 505 stops rising in frequency. This technique can be much faster than gated video, for example, because multiple buckets can be measured during each burst.

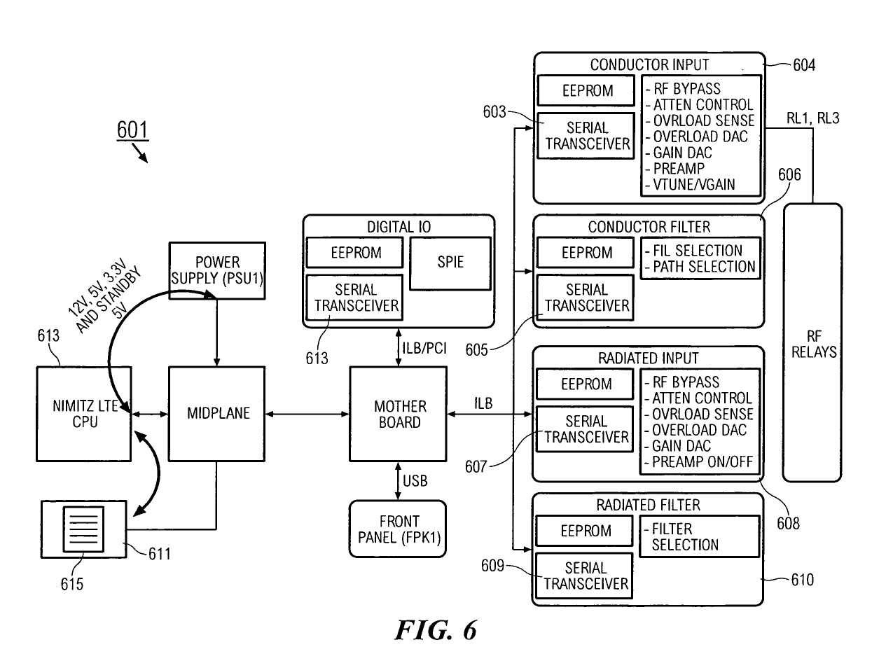

FIG. 6 is a system level block diagram showing the preselector digital control components 601 for controlling the preselector 103. Serial transceiver CPLDs (Complex Programmable Logic Devices) 603, 605, 607, 609 communicate with a serial transceiver CPLD 613. Also shown is the DLP loaded into the spectrum analyzer 105 for controlling the preselector 103.

The controls for the conducted input section 203 are provided by the serial transceiver 603 of conductor input control logic 604. The serial transceiver 603 provides control of the step attenuator 245, input switch control signals to control the relay switch section 207, overload voltage threshold DAC number, overload sense to acquire the signal from the overload detector 255, tuning of DAC numbers, fine gain DAC number and on/off control of the variable gain and step gain preamplifiers 251, 253.

The controls for the conducted filter section 209 are provided by the serial transceiver 605 of conductor filter control logic 606. The serial transceiver 605 provides control of the filter selection between the filter banks 211, 213 and provides on-board relay switch control signals to control the switch 249.

The controls for the radiated input section 205 are provided by the serial transceiver 607 of radiated input control logic 608. The serial transceiver 607 provides control of the step attenuator 225, on-board relay switch control signals to control the switch 285, course gain signals controlling the step gain of the amplifier 233 and variable gain of the amplifier 231, overload voltage threshold DAC number, overload sense to acquire the signal from the overload detector 237 and on/off control of the preamplifiers 231, 233.

The controls for the radiated filter board 215 are provided by a serial transceiver 609 of radiated filter control logic 6010. The serial transceiver 609 provides control of the filter selection between the filter banks 217, 219 and, on-board relay switch control signals to control the switch 229.

As the LO 505 sweeps the measurement frequency of the spectrum analyzer 105 through multiple frequency bands, the preselector 103 is switched between filter paths having frequency bands corresponding to the frequency band being swept by the spectrum analyzer 105. The preselector 103 and spectrum analyzer 105 are synchronized with each other so that this switching can occur at the appropriate time. Moreover, the synchronization must take into account the amount of time for the switching operation to occur. Otherwise the spectrum analyzer 105 would improperly attempt to measure a signal at a frequency that is not being passed through the preselector. This is due to the switch being in transition from one position to another.

A controller delays the sweeping of the measurement frequency of the spectrum analyzer 105 during intervals when the switches of the preselector 103 are switching between filter paths.

The method for synchronizing the spectrum analyzer 105 frequency sweep and switching of the preselector 103 is now described in more detail.

Measurement parameters of the spectrum analyzer 105 are entered either using the front panel UI of the spectrum analyzer 105 or else remotely through the Ethernet switch or hub 123 passing SCPI commands to the spectrum analyzer 105 through the LAN cable 125.

The spectrum analyzer 105 then updates the preselector 103 with any changes to measurement parameters, for example “start/stop frequency”, “span”, and “resolution bandwidth”, by passing SCPI commands through the LAN cable 127.

Based on the measurement parameters received from the spectrum analyzer 105, the CPU 613 of the preselector 103 executes instructions of software 615 stored within memory storage 611 to calculate the “Gate Length” and “Gate Delay” required for the spectrum analyzer 105. This information is passed from the preselector 103 to the EMC DLP software 509.

Based on the calculated Gate Length and Gate delay, the preselector 103 triggers the gate 503 by sending a single pulse from the “sweep out” port 129 at the rear of the preselector 103, through the BNC cable 133 and to the “external trigger in” port 131 at the front of the spectrum analyzer 105. This is followed by sending a sequence of pulses from the “trigger out” port 135 of the preselector 103, through BNC cable 139 and to the “trigger in” port 137 at the rear of the spectrum analyzer 105. This sequence of pulses drives the sweep of each spectrum analyzer bucket using the gated sweep of the spectrum analyzer 105. Thus the controller or CPU 613 of the preselector 103 executes instructions of software 615 stored within memory storage 611 to delay the sweeping of the measurement frequency during intervals when the switches are switching between filter paths. This is done by controlling the activation of the gate 503 of the gated local oscillator 505.

The “Gate Length” is the interval of time for the gate 503 to be open (the contact is in a closed position allowing a signal to pass from the scan generator 501 to the LO 505). The LO 505 sweeps its frequency during the Gate Length interval. When the spectrum analyzer 105 receives a rising edge of the pulse, it will open the gate 503 for a specific Gate Length interval of time and then the gate 503 will close automatically.

For every sweep point of the spectrum analyzer 105, the Gate Length (in time units) is:

Gate Length=(sweep time)/(sweep points−1)

where the “sweep time” is the time it takes for the spectrum analyzer 105 to sweep through the frequency span and the “sweep points” is the number of sweep points the spectrum analyzer 105 is set to measure. In one example the spectrum analyzer 105 has a maximum of 8192 “sweep points”.

The Gate Length needs to be configured so that the LO 505 will stop (gate closed) whenever preselector 103 needs to switch between filters in the filter banks 211, 213, 217, 219. Therefore a “Gate Factor” is incorporated into the Gate Length calculation. Because each filter bandwidth is not the same, it is first determined what is the minimum gate factor that can be applied so that the LO 505 can stop at the correct frequency before switching to the next filter. In the preselector 103 design, there is a small intercept section between the pass-bands of adjacent filters called the “filter overlap” region as illustrated in FIG. 8. The minimum Gate Factor is determined from the filter overlap region so that the LO will always stop inside the intercept section:

Gate Factor=(Filter Overlap Region*Sweep Time)/(Gate Length*Span)

The Gate Factor is applied to the Gate Length as below:

Gate Length with Factor=Gate Factor*Gate Length

The Gate Delay is needed since the spectrum analyzer 105 requires some time for the LO 505 to settle before it starts sweeping. The rising edge pulse period that the preselector 103 needs for sending to the spectrum analyzer 105 is equivalent to Gate Length+Gate Delay.

With this information above, it is determined how many pulses are needed to sweep from one filter to the next filter. To do this, the Gate Length is converted from time to frequency. This frequency calculation of the Gate Length is the “Interval Width” and is determined by:

Interval Width=(Gate Length/PSA Sweep Time)*Span

The number of pulses needed to generate for the current filter before switching to the next filter is:

Pulse Number=(Start Freq of next filter−Start Freq of Current Filter)/Interval Width

Every time the spectrum analyzer 105 sees the rising edge of the pulse, it will open the gate 503 and the LO 505 will start sweeping. When the preselector 103 is required to switch between filters in the filter banks 211, 213, 217, 219, it will stop sending pulses immediately and it will switch to the correct filter and then start sending train of pulses to PSA again. The preselector 103 thus sends pulses to the spectrum analyzer 105 based on the calculated “Gate Length” and “Gate Delay”. The pulses can have a duration of: Gate Length+Gate Delay.

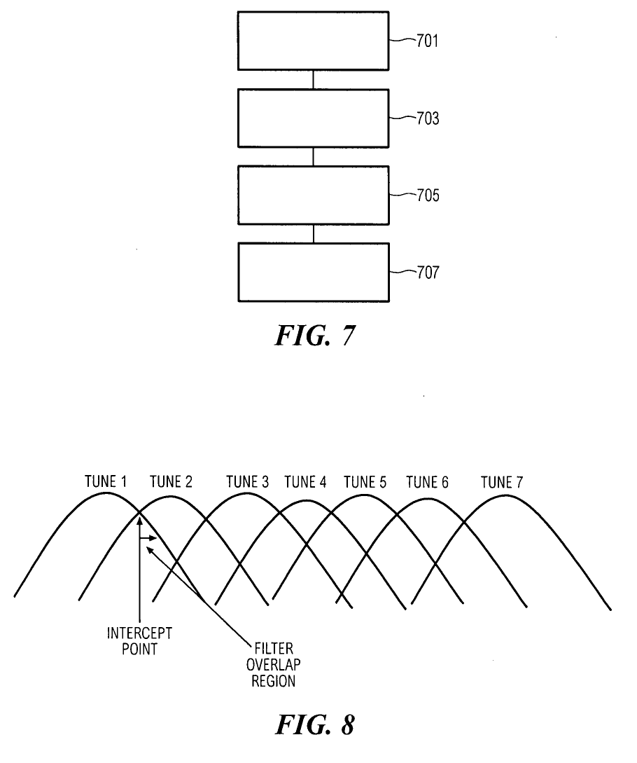

The steps of a method for synchronizing a spectrum analyzer frequency sweep and an external switch of the present invention is illustrated in FIG. 7. The steps include: entering measurement parameters into a spectrum analyzer 701; transmitting updates of the measurement parameters from the spectrum analyzer to a separate preselector 703; calculating, by the preselector, the required Gate Length and Gate Delay of a gated local oscillator of the spectrum analyzer to delay the sweeping of the measurement frequency of the spectrum analyzer during intervals when the switches of the preselector are switching between filter paths 705; and transmitting pulses from the preselector to the spectrum analyzer to control the gated local oscillator to delay the sweeping of the measurement frequency of the spectrum analyzer during intervals when the switches of the preselector are switching between filter paths 707.

In the foregoing specification, the invention has been described with reference to specific exemplary embodiments thereof. The specification and drawings are, accordingly, to be regarded in an illustrative sense rather than a restrictive sense.

1. A measuring receiver comprising:
a spectrum analyzer having a local oscillator for sweeping the measurement frequency of the spectrum analyzer through multiple frequency bands;
a preselector having multiple filter paths with frequency bands corresponding to frequency bands of the spectrum analyzer, the filter paths for passing signals through the preselector and outputting filtered signals to the spectrum analyzer;
switches of the preselector for switching between filter paths to switch in a filter path having a frequency band corresponding to a frequency band being swept by the spectrum analyzer; and
a controller to delay the sweeping of the measurement frequency during intervals when the switches are switching between filter paths.

2. The measuring receiver of claim 1 wherein the spectrum analyzer further comprises a gated local oscillator and the controller delays the sweeping of the measurement frequency by controlling the activation of a gate of the gated local oscillator.

3. The measuring receiver of claim 1, herein the measuring receiver is an EMI receiver.

4. The measuring receiver of claim 3, wherein the EMI receiver has a measurement accuracy of at least +/−1 dB.

5. The measuring receiver of claim 1, wherein the filtered paths include conducted paths for measuring conducted emissions, radiated paths for measuring radiated emissions, and the switches switch between the conducted paths and radiated paths.

6. The measuring receiver of claim 1, wherein the preselector and spectrum analyzer are enclosed in separate housings attachable to each other by cables.

7. The measuring receiver of claim 1, wherein the sweeping of the measurement frequency of the spectrum analyzer includes sweeping frequencies in the range from 9 kHz to 1 GHz.

8. The measuring receiver of claim 1, wherein the preselector further comprises storage media storing code for performing the steps of:
receiving updates of the measurement parameters from the spectrum analyzer to a separate preselector;
calculating, by the preselector, intervals for opening and closing a gate of a gated local oscillator of the spectrum analyzer to delay the sweeping of the measurement frequency of the spectrum analyzer during intervals when the switch of the preselector is switching between filter paths; and
transmitting control signals from the preselector to the spectrum analyzer to control the gated local oscillator to delay the sweeping of the measurement frequency of the spectrum analyzer during intervals when the switch of the preselector is switching between filter paths.

9. The measuring receiver of claim 1, wherein the delay is controlled based on calculated gate length of the spectrum analyzer.

10. The measuring receiver of claim 9, wherein the delay is controlled based on the sum of the calculated gate length of the spectrum analyzer and the gate delay of the spectrum analyzer.

11. A method for synchronizing a spectrum analyzer frequency sweep and an external switch comprising the steps of:
entering measurement parameters into a spectrum analyzer;
transmitting updates of the measurement parameters from the spectrum analyzer to a controller of the external switch;
calculating, by the controller, intervals for opening and closing a gate of a gated local oscillator of the spectrum analyzer to delay the sweeping of the measurement frequency of the spectrum analyzer during intervals when the switch of the preselector is switching between filter paths; and
transmitting control signals from the controller to the spectrum analyzer to control the gated local oscillator to delay the sweeping of the measurement frequency of the spectrum analyzer during intervals when the switch is switching between filter paths.

12. The method of claim 11, wherein the sweeping of the measurement frequency of the spectrum analyzer includes sweeping frequencies in the range from 9 kHz to 1 GHz.

13. The method of claim 11, wherein the delay is controlled based on calculated gate length of the spectrum analyzer.

14. The method of claim 13, wherein the delay is controlled based on the sum of the calculated gate length of the spectrum analyzer and the gate delay of the spectrum analyzer.

15. A preselector of a measuring receiver comprising:
an input port for receiving an input signal from a signal source;
an output port for sending a filtered signal to a spectrum analyzer;
a filtered path for pre-filtering the input signal and outputting the pre-filtered input signal to the output port to measure filtered path calibration data;
a bypass path for passing the input signal to the output port to measure bypass path calibration data;
a switch for switching the signal between the filtered path and the bypass path; and
a controller for transmitting control signals from the preselector to the spectrum analyzer to control a gated local oscillator of the spectrum analyzer to delay the sweeping of the measurement frequency of the spectrum analyzer during intervals when the switch of the preselector is switching between filter paths.

16. The preselector of claim 15, wherein the delay is controlled based on calculated gate length of the spectrum analyzer.

17. The preselector of claim 16, wherein the delay is controlled based on the sum of the calculated gate length of the spectrum analyzer and the gate delay of the spectrum analyzer.
